(19) United States
(12) Patent Application Publication
(10) Pub. No.: US 2015/0295102 A1
(43) Pub. Date: Oct. 15, 2015

(54) SOLAR CELL AND PROCESS FOR MANUFACTURING A SOLAR CELL

(71) Applicant: SolarWorld Innovations GmbH, Freiberg (DE)

(72) Inventors: Lars Philipp Richter, Freiberg (DE); Roman Schiepe, Dresden (DE); Maria Muehlbauer, Lohberg (DE); Stefan Steckemetz, Freiberg (DE)

(21) Appl. No.: 14/686,801

(22) Filed: Apr. 15, 2015

(30) Foreign Application Priority Data
Apr. 15, 2014 (DE) 10 2014 105 358.3

(51) Int. Cl. H01L 31/0224; H01L 31/18

(52) U.S. Cl. CPC H01L 31/02245; H01L 31/1868; H01L 31/18

(57) ABSTRACT

In various embodiments, a solar cell is provided, comprising: a substrate with a front-side and a rear-side, wherein at least the front-side receives light; a passivation layer on the rear-side of the substrate; local contact openings, which pass through the passivation layer and partially expose the rear-side of the substrate; and a first rear-side metallization on the passivation layer and in the local contact openings; wherein the plurality of the local contact openings are disposed such that they are completely covered by the first rear-side metallization.

### CROSS-REFERENCE TO RELATED APPLICATION

This application claims priority to German Patent Application Serial No. 10 2014 105 358.3, which was filed Apr. 15, 2014, and is incorporated herein by reference in its entirety.

### TECHNICAL FIELD

The invention relates to a solar cell and a process for manufacturing a solar cell.

### BACKGROUND

In order to reduce the recombination losses on the rear-side contact of a solar cell, in addition to the emitter, even the rear-side can be passivated, e.g. in the form of a PERC (Passivated Emitter and Rear Cell) solar cell.

Generally, a passivation layer (usually made of Silicon Nitride) is applied on the rear-side of the solar cell substrate in a PERC solar cell and by the passivation layer, local contact openings are made which pass through the passivation layer and partially expose the rear-side of the solar cell substrate. Further, a rear-side metallization is formed on the passivation layer and in the local contact openings. Generally, an aluminum paste is used for forming the rear-side metallization. However, it has been shown that relatively large and undesired aluminum beads are formed in different structures by using an aluminum paste.

### SUMMARY

According to various embodiments, a solar cell is provided, comprising: a substrate with a front-side and a rear-side, wherein at least the front-side receives light; a passivation layer on the rear-side of the substrate; local contact openings, which pass through the passivation layer and partially expose the rear-side of the substrate; and a first rear-side metallization on the passivation layer and in the local contact openings; wherein the plurality of the local contact openings are disposed such that they are completely covered by the first rear-side metallization.

According to various embodiments, the local contact openings can be configured in the form of linear trenches (also known as LCO Finger).

The beads formed were generally removed manually, so that the solar cells could be classified. However, the manual removal of the beads is not considered for the mass production of a wide range of solar cells. This would make that many Al-pastes cannot be used for the mass production, although the pastes have very good other properties.

Furthermore, efforts have been made to avoid the bead formation, whereby until now, those pastes were used which avoid the bead formation. Although, the beads can be avoided with special aluminum pastes, the aluminum pastes without “bead formation” used until now; however have a lower efficiency, a poorer paste adhesion and a higher lead content.

In various embodiments, a solar cell and a process for manufacturing a solar cell are provided in which or by which a reduction or even prevention of the aluminum bead formation can be achieved during the rear-side metallization of a solar cell with local contact openings on the rear-side of the solar cell. For example, this can be achieved without being restricted to the selection of a particular aluminum paste. In other words, therefore, basically all aluminum pastes can be used without any relevant aluminum bead formation.

In various embodiments, the formation or emergence of aluminum beads as manufacturer's mark, for example, at the exits of the trenches of the local contact openings (LCOs) made of aluminum paste in the peripheral region, for example, of PERC (Passivated Emitter and Rear Cell) solar cells, at the contact pads and/or at the paste recesses (for example, aluminum paste recesses) is avoided.

In various embodiments, a complete coverage of the local contact openings on the rear-side of a rear-side passivated solar cell, for example—a PERC solar cell, is clearly provided for avoiding beads (for example, a complete coverage of the LCO trenches for avoiding beads).

In various embodiments, a solar cell is provided, comprising: a substrate with a front-side and a rear-side, wherein at least the front-side receives light; a passivation layer on the rear-side of the substrate; local contact openings which pass through the passivation layer and partially expose the rear-side of the substrate; a first rear-side metallization on the passivation layer and in the local contact openings; wherein the plurality of the local contact openings are disposed such that they are completely covered by the first rear-side metallization.

The front-side can also be referred to as light incident side of the solar cell, wherein it should be noted that the various embodiments can also be provided for, for example—the so-called bifacial solar cells, for example—so-called bifacial PERC solar cells. A bifacial solar cell is a solar cell which also has a grating (grid) made of contact fingers (for example, made of aluminum) on the rear-side thereof.

In other words, the majority of the local contact openings are disposed such that they do not extend beyond the periphery of the first rear-side metallization.

By the complete coverage, it is achieved that the bead formation of the material of the first rear-side metallization is significantly reduced, for example—even avoided. The material of the first rear-side metallization is not restricted to a particular aluminum paste, but basically all metal pastes, for example—all aluminum pastes can be used for forming the first rear-side metallization.

In a configuration, the distance of the local contact openings to the edge of the first rear-side metallization is at least 10 μm, for example—at least 50 μm. At this minimum distance, it has become evident that a particularly reliable prevention of bead formation is achieved.

The first rear-side metallization can include aluminum.

According to various embodiments, the rear-side metallization has flat openings, which partially expose the passivation layer. In other words, the solar cell can have flat openings in the first rear-side metallization, which partially expose the passivation layer.

Furthermore, the solar cell can have flat openings in the first rear-side metallization, which have a second, for example—well solderable, metallization (also referred to as second metallization) include, for example—Silver, Nickel and/or Zinc, for example—in pure form or in the form of an alloy with one or with several other metals, for example—with one or with several of the respective other above-mentioned metals.

In the local contact openings, another metal can be included as the metal of the first rear-side metallization, for example—Silver can be included in the local contact openings for forming a respective local contact with the rear-side of the substrate of the solar cell.

According to various embodiments, the flat openings can divide the first rear-side metallization into a plurality of rear-side metallization segments which are respectively disposed at a distance from each other, wherein each contact opening of the plurality of local contact openings is completely covered by a rear-side metallization segment (also referred to as Finger) of the plurality of rear-side metallization segments. In other words, the rear-side metallization can have several rear-side metallization segments, which are spatially separated from each other.

According to various embodiments, the solar cell can also have at least one more local contact opening in the form of a linear trench, which passes through the passivation layer and partially exposes the rear-side of the substrate, wherein the further local contact opening is formed such that this is partially covered by the first rear-side metallization. In other words, the solar cell can have at least one contact opening which is not completely covered by the rear-side metallization. Thereby, the alignment of the rear-side metallization, e.g. of the rear-side metallization segments with respect to the contact openings can be improved.

According to various embodiments, the further local contact opening can be interrupted at least at one end section which protrudes beyond the first rear-side metallization.

According to various embodiments, the rear-side metallization segments can be strip-shaped, or can be formed strip-shaped. In other words, the solar cell can have a strip-shaped rear-side metallization. Alternatively or additionally, the rear-side metallization segments can be star-shaped, or can be formed star-shaped. In other words, the solar cell can have star-shaped rear-side metallization.

Furthermore, the second metallization can be located on unopened passivation layer regions.

Further, in various embodiments, a process is provided for manufacturing a solar cell. The process can include: forming a passivation layer on the rear-side of a substrate; forming of local contact openings through the passivation layer, so that the rear-side of the substrate is partially exposed; and forming a first rear-side metallization on the passivation layer and in the local contact openings; wherein the local contact openings are disposed such that they are completely covered by the rear-side metallization.

The local contact openings can be formed by means of Laser beam. Therefore, the extension of the local contact openings can be restricted by controlling the Laser beam. Furthermore, in case of using one or more Laser and thereby, in case of the local contact openings by means of the Laser beam, the extension of the local contact openings is restricted by using at least one shadow-mask.

Alternatively, the local contact openings can be, for example—etched.

In still another configuration, the local contact openings can be formed such that the distance from each single local contact opening of the local contact openings to the edge of the rear-side metallization is at least 10 μm, for example—at least 50 μm.

According to various embodiments, the first rear-side metallization has flat openings, which partially expose the passivation layer; wherein the flat openings divide the first rear-side metallization into a plurality of rear-side metallization segments which are respectively disposed at a distance from each other, wherein each contact opening of the plurality of local contact openings is completely covered by a rear-side metallization segment of the plurality of rear-side metallization segments.

According to various embodiments, the flat openings can be formed or are formed, in which the rear-side metallization segments are or to be formed in the form of stripes.

Alternatively, the flat openings are or to be formed, in which a portion of the rear-side metallization is or to be removed. In other words, the rear-side metallization can be or is formed completely and can be or is partially opened for forming the flat openings.

According to various embodiments, the process can further includes: forming of at least one more local contact opening in the form of a linear trench, which passes through the passivation layer and partially exposes the rear-side of the substrate, wherein the further contact opening is formed such that this is partially covered by the first rear-side metallization. For example, one or two (opposite) end sections of the further contact opening can be exposed.

According to various embodiments, the further local contact opening can be configured interrupted at one or two end sections thereof, which protrudes beyond the first rear-side metallization.

### BRIEF DESCRIPTION OF THE DRAWINGS

Exemplary embodiments of the invention are represented in the figures and will be explained in more details in the following.

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 showing a schematic cross-sectional view of a solar cell according to various embodiments;

FIG. 2 showing a rear-side view on a section of a conventional solar cell, in which aluminum beads are represented;

FIG. 3 showing a rear-side view on a section of a solar cell according to various embodiments;

FIG. 4 showing a rear-side view on a section of a conventional solar cell, in which aluminum beads are represented;

FIG. 5 showing a rear-side view on a section of a solar cell according to various embodiments;

FIG. 6 showing a rear-side view on a section of a conventional solar cell, in which aluminum beads are represented;

FIG. 7 showing a rear-side view on a section of a solar cell according to various embodiments;

FIG. 8 showing a flow-diagram, in which the process for manufacturing a solar cell according to various embodiments is represented;

FIG. 9 showing a rear-side view of a solar cell according to various embodiments;

FIG. 10 showing a rear-side view on a section of a solar cell according to various embodiments;

FIG. 11 showing a rear-side view on a section of a solar cell according to various embodiments;

FIG. 12 showing a rear-side view on a section of a solar cell according to various embodiments; and

FIG. 13 showing a rear-side view at a section of a solar cell according to various embodiments.

### DESCRIPTION

In the following detailed description, a reference is made to the accompanying drawings, which form part of this and in which, specific embodiments in which the invention can be performed, are shown for illustration. In this regard, the directional terminology, such as “above”, “below”, “front”, “behind”, “anterior”, “posterior” etc. are used with reference to the orientation of the described figure(s). Since components of the embodiments can be positioned in a number of different orientations, the directional terminology is used for illustration and is not limiting in any way. Obviously, other embodiments can be used and structural or logical changes can be made without departing from the scope of protection of the present invention. It must be understood that the features of the various embodiments described herein can be combined with each other, unless specified otherwise. Therefore, the following detailed description shall not be comprehended in a restrictive sense, and the scope of protection of the present invention is defined by the annexed claims.

The terms “linked”, “connected” and “coupled” within the scope of this description are used for describing a direct as well as an indirect linkage, a direct or indirect connection and a direct or indirect coupling. In the figures, identical or similar elements are provided with identical reference numerals as far as this is appropriate.

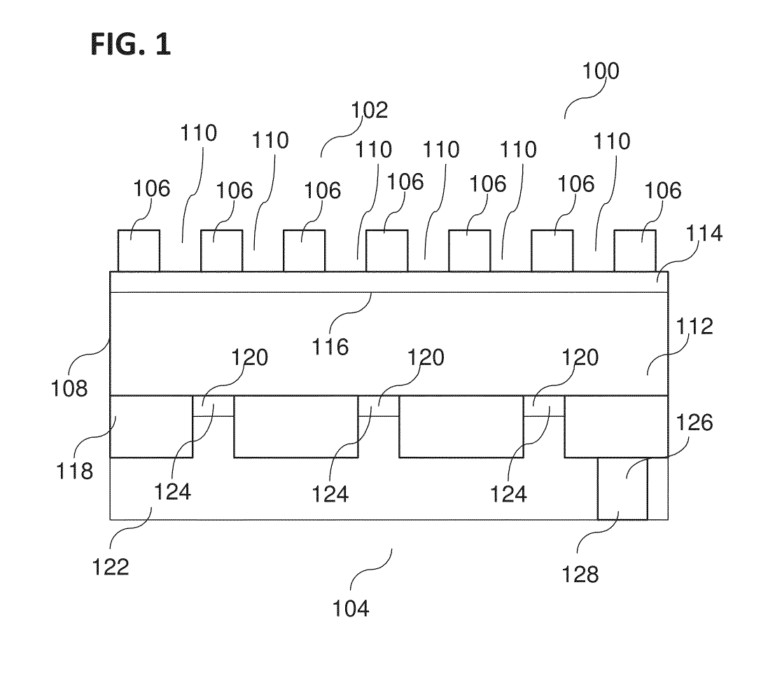

FIG. 1 shows a schematic cross-section of a solar cell 100 according to various embodiments.

The solar cell 100 can be a silicon solar cell 100, for example—a crystalline silicon solar cell 100.

The solar cell 100 can be or is made in the form of one of the following types: passivated emitter and rear-side solar cell (passivated emitter and rear-side cell—PERC), and/or locally diffused, passivated rear-side solar cell (passivated rear locally diffused cell—PERL).

In various embodiments, the solar cell 100 can have a face (also referred to as front-side) 102 and a rear-side 104. The face 102 can also be referred to as light incident side 102 of the solar cell 100, wherein it should be noted that the various embodiments can also be provided for, for example—so-called bifacial solar cells, for example—so-called bifacial PERC solar cells. A bifacial solar cell is a solar cell which also has a grating (grid) made of contact fingers (for example—made of aluminum) on the rear-side 104 thereof (not shown in the figures).

The solar cell 100 optionally has a plurality of front-side contacts 106 on the front-side 102 thereof, which are applied on a solar cell substrate 108 and are clearly used for collecting the electrical charge carriers generated in the solar cell substrate 108. The solar cell substrate 108 has an optically active region 110.

The front-side contacts 106 can be formed directly on the front-side of the solar cell substrate 108, i.e. on the light-facing front-side 102. The front-side contacts 106 can be formed, for example—as front-side metallization. The front-side contacts 106 can be configured structured over the optically active region 110, for example—finger-shaped as metallization (in the form of the so-called contact finger) or in the form of a selective emitter or as a combination of two. A structured formed front-side metallization can be configured, for example—essentially (except for electrical cross-links) only on the optically active region 110.

The optically active region 110 of the solar cell 100 includes an electrically conducting and/or semiconducting material, for example—a doped Silicon, for example—p-doped (p-type), for example—with doping of Boron, Gallium and/or Indium; or n-doped (n-type), for example—with doping of Phosphorous, Arsenic and/or Antimony.

The optically active region 110 can absorb electromagnetic radiations and make a photo current therefrom. The electromagnetic radiation can have range of wavelengths, which includes X-ray radiation, UV-radiation (A to C), visible light and/or Infrared radiation (A to C).

The optically active region 110 includes the first region 112 which is doped with a dopant type different from the second region 114 and remains in a physical contact with this. For example, the first region 112 can be a p-type (doped with p-dopant(s)) and the second region 114 can be an n-type (doped with n-dopant(s)) and vice-versa. A pn-junction is configured at the interface 116 of the first region 112 with the second region 114, at which positive and negative charge carriers (holes and electrons) can be separated. The optically active region 110 can have several pn-junctions, for example—side by side and/or one upon the other.

A rear-side contact structure is configured on the rear-side 104 of the solar cell 100. The rear-side contact structure can include a dielectric layer structure 118 and a first rear-side metallization 122. The dielectric layers 118 can include one or more dielectric layers. In the dielectric layer structure 118, in other words, by the dielectric layer structure 118, a plurality of so-called local contact openings 120 can be configured which partially expose the rear-side of the solar cell substrate 108.

The local contact openings 120 can be formed as trenches (in any cross-section and in any shape) in various embodiments, for example—by means of a Laser beam or by means of several Laser beams, which can be generated by one or more Lasers. The extension of the local contact openings 120 can be restricted by controlling the Laser beam. Furthermore, the extension of the local contact openings 120 can be restricted by using at least one shadow-mask. Alternatively, the local contact openings 120 can be etched in various embodiments. It should be noted that the local contact openings 120 can be formed as trenches in any desired shape.

In an exemplary embodiment, the dielectric layer structure 118 (also referred to as passivation layer 118) can include a first dielectric layer, wherein the first dielectric layer is configured, disposed or deposited on or above the optically active region 110 on the rear-side 104 of the solar cell substrate 108. Furthermore, the dielectric layer structure 118 can include a second dielectric layer. The second dielectric layer can be configured, disposed or deposited on or above the first dielectric layer.

The first dielectric layer can have or be made of, for example—the same material as the second dielectric layer. The first dielectric layer can include, for example—Silicon Nitride (Si3N4), Silicon Oxide (SiO2) and/or Silicon Oxynitride (SiON), alternatively, for example—Aluminum Oxide (Al2O3) as well. The first dielectric layer can have, for example—a lower refractive index than the second dielectric layer. Generally, the dielectric layer structure 118 can have each material suitable for the passivation of the rear-side of the solar cell substrate 108, on which the material (for example, aluminum) of the first rear-side metallization cannot alloy, as explained in more details in the following.

For example, the dielectric layer structure 118 can include a layer thickness in a range of approximately 10 nm to approximately 500 nm, for example, in a range of approximately 20 nm to approximately 250 nm.

Furthermore, the rear-side contact structure of the solar cell 100 can include a first rear-side metallization 122. The first rear-side metallization 122 can include, for example—aluminum and can be provided on the exposed side of the passivation layer 118 as well as in the local contact openings 120. Furthermore, for forming a physical contact and an electrical contact with the exposed areas of the rear-side of the solar cell substrate 108, a respective metallic coating 124, for example a Silver coating 124 can be provided in the local contact openings 120 (in other words, for forming a respective local contact with the rear-side of the solar cell substrate 108). The metal of the first rear-side metallization can or may be applied on the metal coating 124, for example—the Silver coating 124 in the local contact openings 120 in various embodiments.

Further, flat openings 126 in the rear-side metallization 122 can be provided in various embodiments, which include a second, for example—well solderable metallization 128 (also referred to as second rear-side metallization 128), such as Silver, Nickel, and/or Zinc. The second metallization 128 can be placed on the unopened passivation layer areas, as is exemplarily represented by means of a flat opening 126 in FIG. 1.

The rear-side contact structure can be used for tapping the light-induced charge carrier, which can be carried off by the local contact openings 120 from the optically active region 110 of the solar cell substrate 108. In other words: the dielectric layer structure can have one or more electrically conductive regions, which are configured for an electrical contact of the optically active region, for example—as through contacts or interconnections. The through contacts 122, 124 can be configured as electrically conductive regions in the passivation layer 118 such that a continuous electro-conductive connection is configured through the passivation layer 118 and thereby clearly through the overall dielectric layer structure 118.

In various embodiments, a solar cell module with several of the above-described solar cells 100 can be configured, wherein the several solar cells are electrically interconnected in series and/or in parallel.

The structures of the rear-side 104 of the solar cell 100 described in the following, can be provided individually or together in the solar cell 100 according to various embodiments.

For simpler representation of the various embodiments, a corresponding conventional rear-side structure of the local contact openings with reference to the first rear-side metallization is respectively described for each individual structure according to various embodiments.

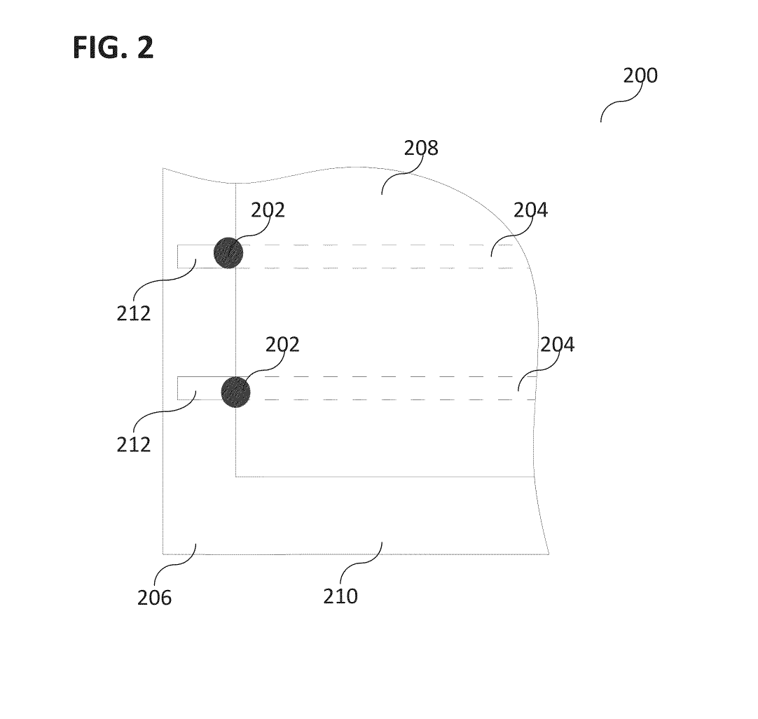

FIG. 2 shows a rear-side metallization 200 on a conventional solar cell, in which aluminum beads 202 are represented. More precisely, a plurality of local contact openings (for example, LCO—trenches) 204 through a passivation layer 206 is represented in the rear-side view 200, wherein the local contact openings 204 are only partially covered by an aluminum rear-side metallization 208, so that the region 210 of the passivation layer 206 and the region 212 of the local contact openings 204 remains not covered by the aluminum rear-side metallization 208.

Therefore, FIG. 2 clearly shows a section of the conventional PERC solar cell. The LCO trenches (Local Contact Opening) 204 protrude out of the aluminum rear-side metallization 208 on the left side in FIG. 2. It has become evident that the thick aluminum beads 202 can primarily form at these positions.

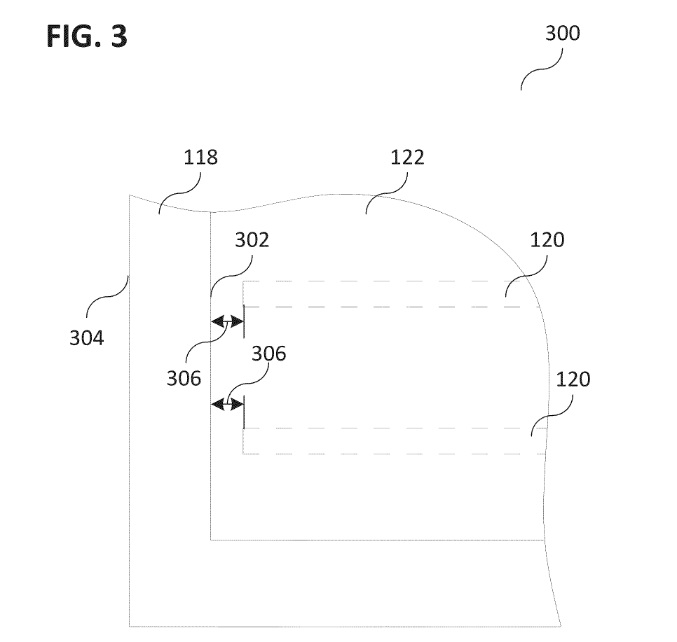

FIG. 3 shows a rear-side view 300 on a solar cell 100 according to various embodiments.

For avoiding the formation of aluminum beads 202, as they are shown in FIG. 2, it is provided in various embodiments that the local contact openings 120 are disposed such that they are completely covered by the first rear-side metallization 122. In other words, it means that the local contact openings 120 end before they “exit” the first rear-side metallization 122 (for example, the aluminum paste). In various embodiments, a portion of the passivation layer 118 remains not covered by the first rear-side metallization 122 in order to avoid a short circuit with the front-side 102 of the solar cell 100. In various embodiments, the distance of the edge 302 of the first rear-side metallization 122 to the wafer edge 304, in other words, to the edge 304 of the solar cell 100 is at least approximately 1 mm, wherein this value is however not critical for the functioning of the solar cell 100.

In various embodiments, the distance 306 of the each local contact opening 120 to the edge 302 of the first rear-side metallization 122 can be at least 10 μm, for example, at least 50 μm. The distances 306 of the local contact openings 120 to the edge 302 can, however, vary and be different.

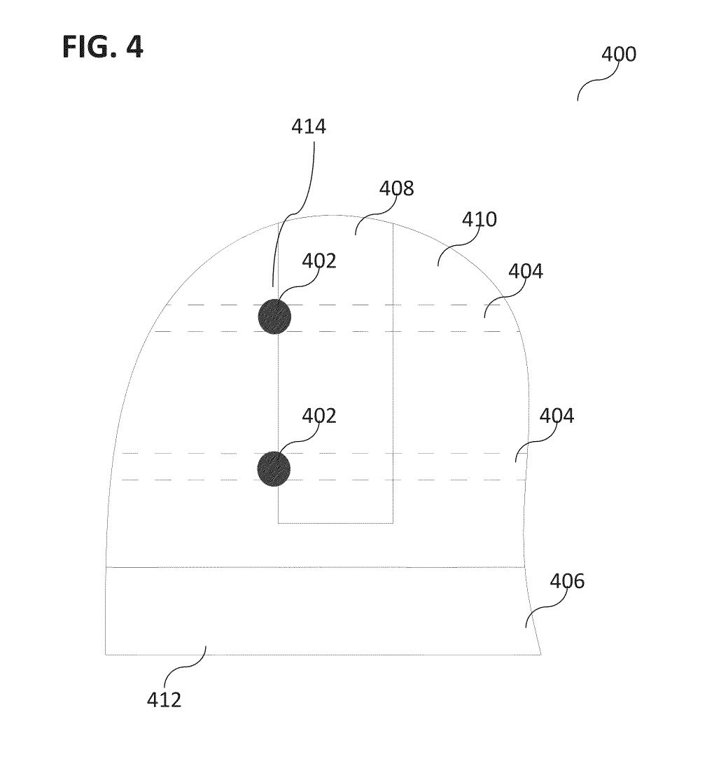

FIG. 4 shows a rear-side view 400 on a conventional solar cell, in which aluminum beads 402 are represented. More precisely, in the rear-side view 400 of the FIG. 4, a plurality of local contact openings (for example, LCO trenches) 404 through the passivation layer 406 are represented. Furthermore, a busbar 408 (or busbar-pad, for example made of Silver, for example Silver paste) is represented, which is disposed, in other words, extends above the local contact openings 404. The local contact openings 404 pass through continuously up to the busbar 408 and under the busbar 404 408. Apart from the busbar 408, the local contact openings 404 are covered by the aluminum rear-side metallization 410, wherein the region 412 of the passivation layer 406 remains not covered by the aluminum rear-side metallization 410. FIG. 4 shows in the section of the conventional PERC solar cell that there is formation of thick aluminum beads 402 in the peripheral region 414 of the busbar 408.

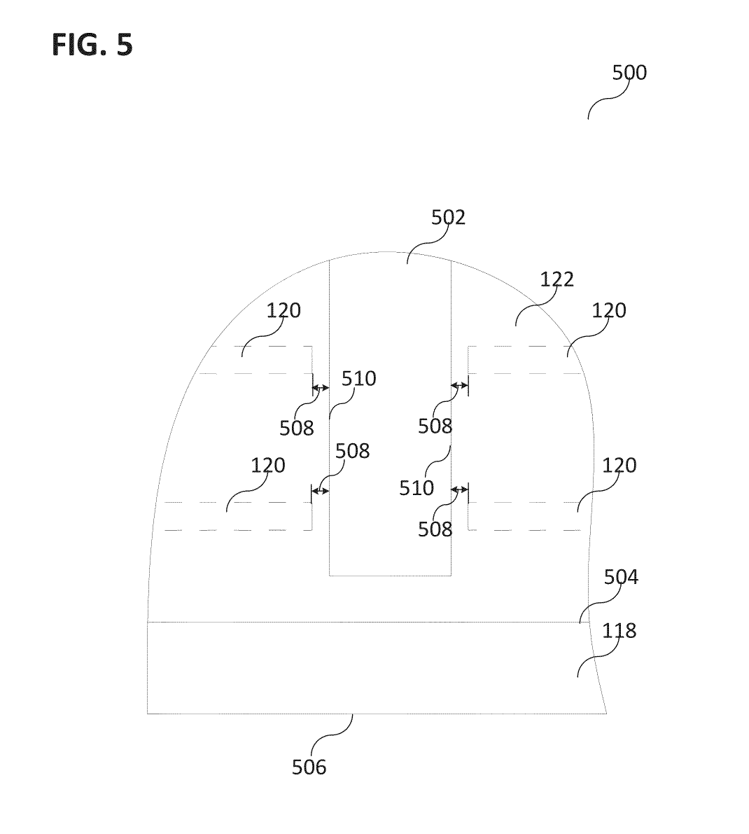

FIG. 5 shows a rear-side view 500 on a solar cell 100 according to various embodiments.

For avoiding the formation of aluminum beads 402, as they are represented in FIG. 4, it is provided in various embodiments that the local contact openings 120 are disposed such that they are completely covered by the first rear-side metallization 122 and do not extend up to one or more busbars (also referred to as rear-side busbars) 502. In other words, it means that the local contact openings 120 end before they “abandon” the first rear-side metallization 122 (for example, the aluminum paste) and thereby do not laterally cut the edges of the busbar or busbars 502. Therefore, one or more busbars 502 can be provided on the rear-side of the solar cell 100, for example made of a metal such as Silver (for example, by means of a metal paste such as a Silver paste) in various embodiments. Clearly, the local contact openings 120 (for example, the LCO contacts 120) end shortly before the busbar or busbars 502 (for example, the Silver busbar or busbars 502).

The distance 508 of the each local contact opening 120 to the edge 510 of the busbar 502, and thereby the edge 510 of the first rear-side metallization 122 can be at least 10 μm, for example at least 50 μm in various embodiments. However, the distances 508 of the local contact openings 120 to the edge 510 can vary and be different.

In various embodiments, a portion of the passivation layer 118 also remains not covered by the first rear-side metallization 122 in order to avoid a short circuit with the front-side 102 of the solar cell 100. In various embodiments, the distance from the edge 504 of the first rear-side metallization 122 to the wafer edge 506, in other words, to the edge 506 of the solar cell 100, is approximately 1 mm, wherein this value is however not critical for the functioning of the solar cell 100.

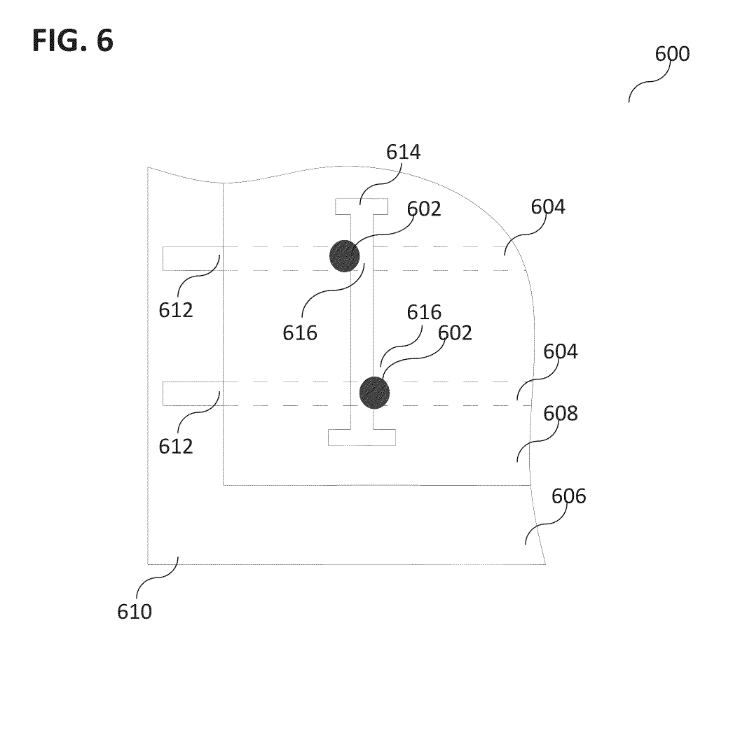

FIG. 6 shows a rear-side view 600 on a conventional solar cell, in which aluminum beads 602 are represented. More precisely, in the rear-side view 600, a plurality of local contact openings (for example, LCO trenches) 604 through the passivation layer 606 are represented, wherein the local contact openings 604 are only partially covered by an aluminum rear-side metallization 608, so that the region 610 of the passivation layer 606 and the region 612 of the local contact openings 604 remain not covered by the aluminum rear-side metallization 608. Furthermore, a recess 614 is represented within the aluminum rear-side metallization 608, which represents the manufacturer's mark 614 in this example, however can generally represent any other information. The recess 614 is disposed above the local contact openings 604. The local contact openings 604 pass through continuously up to the recess 614 and under the recess 614. The local contact openings 604 are covered by the aluminum rear-side metallization 608 except for the recess 614, wherein the region 616 of the passivation layer 606 remains not covered by the aluminum rear-side metallization 608. In the section of the conventional PERC solar cell, FIG. 6 shows that the LCO trenches 604 pass through the aluminum recesses 614, as they are used e.g. for manufacturer's mark. Often, thick aluminum beads 602 form at each exit of the LCO trench 604 out of the aluminum paste 608 in the aluminum recess 614.

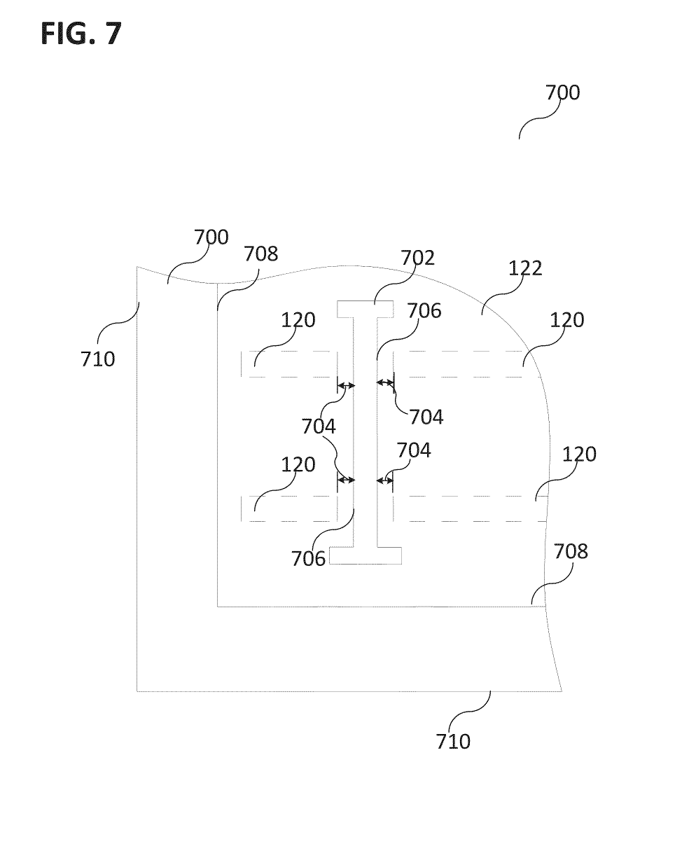

FIG. 7 shows a rear-side view 700 on a solar cell 100 according to various embodiments.

In various embodiments, for avoiding the formation of aluminum beads 602, as they are represented in FIG. 6, it is provided that the local contact openings 120 are disposed such that they are completely covered by the first rear-side metallization 122 and do not extend up to the recess 702, such as they are used for the manufacturer's mark, generally for representing any other information, for example in the form of alphabets, symbols or in other form. In other words, it means that the local contact openings 120 end before they “abandon” the first rear-side metallization 122 (for example, the aluminum paste) and thereby do not laterally cut the edges of the recess 702. Therefore, one or more recesses 702 can be provided on the rear-side of the solar cell 100 in various embodiments. Clearly, the local contact openings 120 (for example, the LCO contacts 120) end shortly before the recess 702 or the recesses 702.

The distance 704 of each local contact opening 120 to the edge 706 of the recess 702 and thereby the edge 706 of the first rear-side metallization 122 can be at least 10 μm, for example at least 50 μm in various embodiments. The distances 704 of the local contact openings 120 to the edge 706 of the recess 702 can however vary and be different.

In various embodiments, a portion of the passivation layer 118 remains not covered by the first rear-side metallization 122 in order to avoid a short circuit with the front-side 102 of the solar cell 100. In various embodiments, the distance from the edge 708 of the first rear-side metallization 122 to the wafer edge 710, in other words, to the edge 710 of the solar cell 100 can be at least approximately 1 mm, wherein this value is however not critical for the functioning of the solar cell 100.

In various embodiments, the local contact openings 120 do no longer protrude out of the first rear-side metallization, for example out of aluminum paste. Further, in various embodiments, the local contact openings 120 can be omitted in the solar cell pad-region. Furthermore, in various embodiments, the local contact openings 120 can be provided interrupted in the region of rear-side metallization recesses (for example, aluminum recesses), which can be provided, for example as manufacturer's marks.

To sum up, for example, many requirements are placed on aluminum pastes for rear-side passivated solar cells (for example, PERC cells) for example:

a highest possible efficiency is desired;

high adhesion on passivation films for the long-term stability of solar cell modules;

avoiding dust and bead formation;

free from heavy metals;

lower paste application;

lower deflection of the solar cells.

It has not been possible to this date to fulfil all the requirements at the same time. Therefore, as described above, pastes with lower bead formation often suffer from poor efficiency, lower paste adhesion and a high lead content. By various embodiments of the complete LCO coverage, now for example, lead-free pastes can also be used for the production with highest potential efficiency and excellent adhesion.

For example, if the LCO trenches on the periphery of the solar cell are led out of the aluminum contact, thus often a thick aluminum bead forms on the periphery of the aluminum contact in LCO trenches. These aluminum beads could be avoided either by intensive optimizations of the drying or firing process. Even a variation in the paste thickness was not successful. Likewise, the recesses in aluminum print, e.g. on the manufacturer's mark cause too thick aluminum beads. The same problem can occur at the peripheries of the rear-side busbars.

In various embodiments, the complete coverage of all LCO trenches with, for example—an aluminum paste is provided in order to avoid these thick aluminum beads. It means that the LCO trenches in the peripheral region of the solar cell must be reduced, so that even the ends of the LCOs are covered with aluminum paste. Alternatively, the aluminum contact can also be printed still closer on the wafer edge in order to achieve a complete coverage of the LCO. In order to avoid the aluminum beads at the recesses in aluminum, such as manufacturer's mark or the like, for example—if the LCOs already end before the aluminum recess, should therefore not run out of the aluminum contact. The same applies for aluminum recesses for busbars and pads. The LCOs should already end before the aluminum recess, in order to avoid thick aluminum beads.

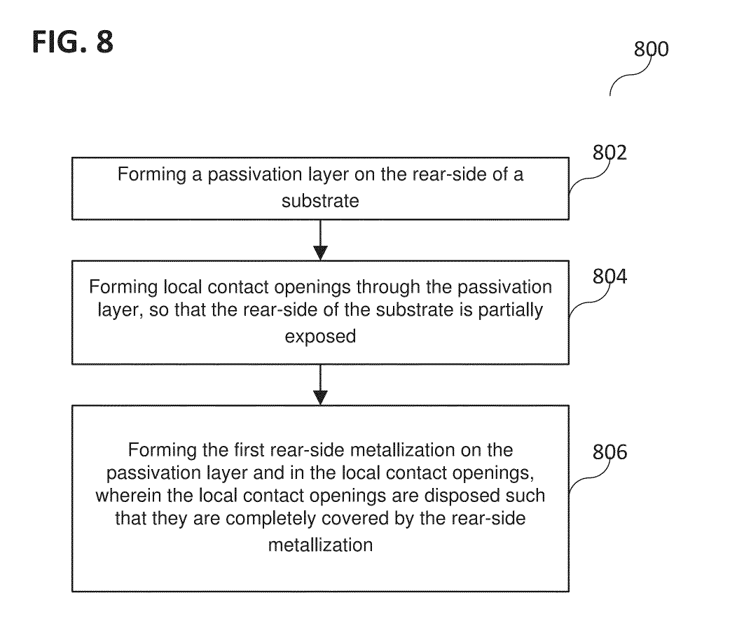

FIG. 8 shows a flow-diagram, in which the process 800 for manufacturing a solar cell according to various embodiments is represented.

The process 800 can include, in 802, forming a passivation layer on the rear-side of a substrate, and in 804, forming local contact openings through the passivation layer, so that the rear-side of the substrate is partially exposed. The process can further include, in 806, forming the first rear-side metallization on the passivation layer and in the local contact openings, wherein the local contact openings are disposed such that they are completely covered by the rear-side metallization.

The local contact openings can be formed by means of Laser beam, wherein the extension of the local contact openings can be restricted by controlling the Laser beam. Further, the extension of the local contact openings can be restricted by using at least one shadow-mask, wherein the shadow-mask can cover, for example—the periphery (for example—right-angled) of the solar cell during the formation of the local contact openings.

Alternatively, the local contact openings can be etched.

The local contact openings can be formed such that the distance from each single local contact opening of the local contact openings to the edge of the rear-side metallization is at least 10 μm, for example—at least 50 μm.

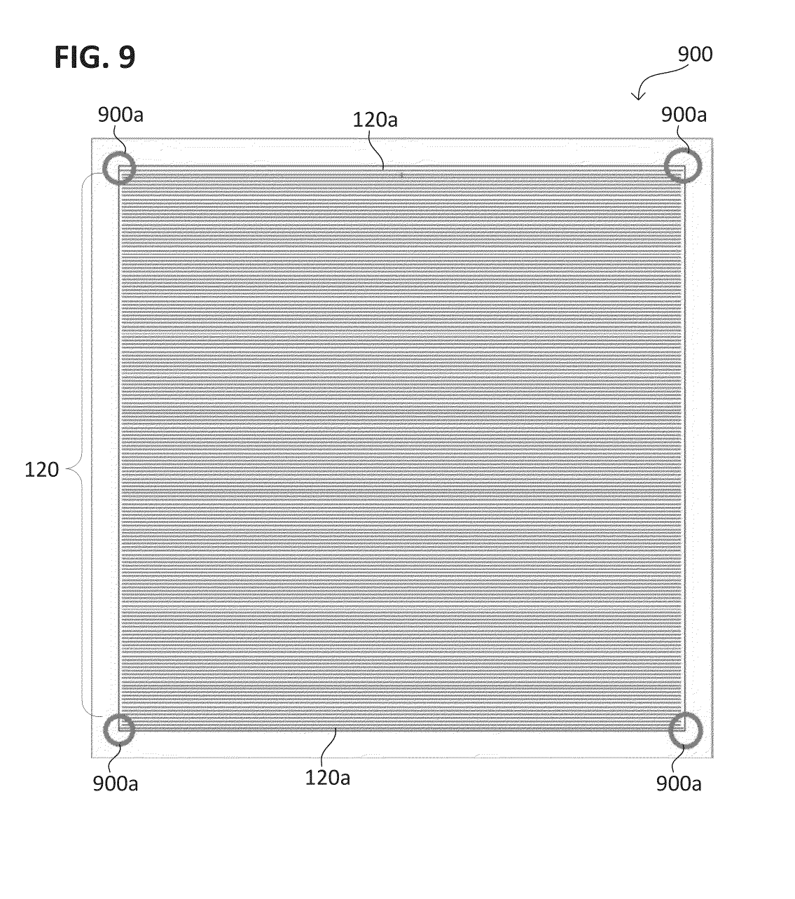

FIG. 9 shows a rear-side view 900 on a solar cell 100 according to various embodiments.

According to various embodiments, the solar cell 100 can have a plurality of local contact openings 120 in the form of linear trenches, as described before. The plurality of local contact openings 120 can respectively have local contact openings 120 aligned essentially parallel to each other, e.g. in a range of approximately 10 numbers to approximately 1000 numbers, e.g. in a range of approximately 100 numbers to approximately 150 numbers. In other words, each local contact opening 120 can be aligned essentially parallel (i.e. with an angular deviation of less than 10, e.g. less than 0.50) with respect to the respective local contact opening adjacent thereof.

The plurality of local contact openings 120 can be or is completely covered by the rear-side metallization (not shown). For example, the local contact openings 120 (also referred to as LCO—Fingers) can be disposed and formed such that they can be or are completely covered by the rear-side metallization 122, i.e. that these end evidently under the rear-side metallization 122.

Further, the solar cell 100 can have further local contact openings 120a, which are only partially covered by the rear-side metallization, so that these are, e.g. partially exposed from the rear-side metallization (can also be referred to as partially exposed local contact openings 120a). The further local contact openings 120a can be aligned essentially parallel to the local contact openings 120.

The further contact openings 120a can be disposed, e.g. on the periphery of the solar cell 100, for example—these can form the upper-most (first) and the lower-most (last) contact opening, as represented in FIG. 9. The ends of the further contact openings 120a (in the encircled region 900a) end shortly before the periphery 304 of the solar cell 100.

According to various embodiments, the distance of the further LCO 120a to the edge 304 (or periphery) of the solar cell 100 (along the longitudinal extension of the further LCO 120a) can be less than the distance of the LCO 120 to the edge 304. The distance of the further LCO 120a to the edge 304 of the solar cell 100 can be less than 500 μm, e.g. less than 100 μm, e.g. less than 10 μm, e.g. in a range of approximately 10 μm to approximately 500 μm.

Alternatively or additionally, the further local contact opening 120a can be disposed at any position of the solar cell, e.g. centrally or e.g. at every ten, every twenty, every fifty or every hundred local contact openings 120. In other words, e.g. at least ten, e.g. at least twenty, e.g. at least fifty or e.g. at least hundred local contact openings 120 can be disposed between two further local contact openings 120a.

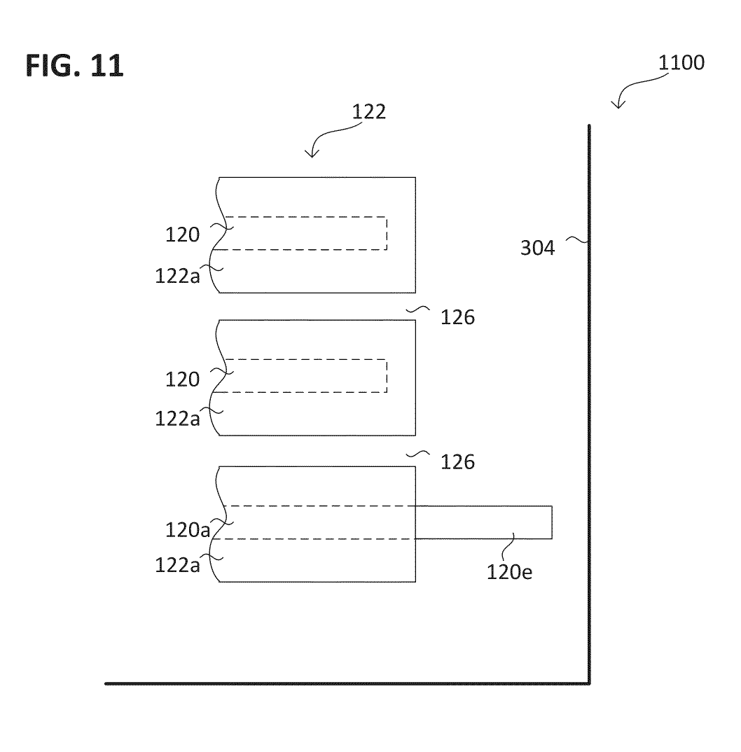

According to various embodiments, the alignment of the local contact openings 120 under the rear-side metallization 122 (e.g. aluminum print) is relieved, e.g. if the rear-side metallization 122 is not completely formed, e.g. when the rear-side metallization 122 includes flat openings 126, which divide the rear-side metallization 122 into several rear-side metallization segments 122a (compare FIG. 11).

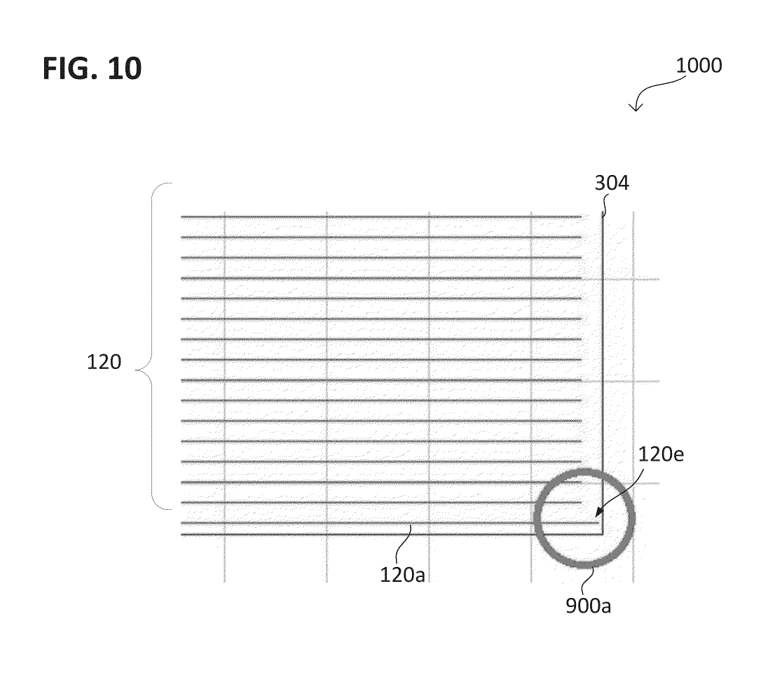

FIG. 10 shows a section 1000 of a rear-side view on a solar cell 100 according to various embodiments.

As is described previously, the end section 120e of the further local contact opening 120a (further LCO 120a) protrudes beyond the ends of the local contact openings 120. In other words, the distance of the end section 120e of the further LCO 120a to the edge 304 (or periphery) of the solar cell 100 can be less than the distance of the LCO 120 to the edge 304. The distance of the end section 120e of the LCO 120a to the edge 304 of the solar cell 100 can be less than 500 μm, e.g. less than 100 μm, e.g. less than 10 μm, e.g. in a range of approximately 10 μm to approximately 500 μm.

For example, an extension of the further local contact opening 120a (i.e. the length thereof) can be configured or is larger than the extension of the local contact openings 120, e.g. longer around the end section 120e or longer on each side around the end section 120e.

Alternatively or additionally, the further local contact opening 120a can be disposed or is offset with reference to the local contact openings 120, e.g. offset at least around the end section 120e.

FIG. 11 shows a section of a rear-side view 1100 on a solar cell 100 according to various embodiments, similar to the view 1000.

According to various embodiments, a rear-side metallization 122 is provided, which is divided into several rear-side metallization segments 122a (also referred to as rear-side metallization fingers). The rear-side metallization segments 122a can be disposed spatially separated from each other, i.e. at a distance from each other.

According to various embodiments, the rear-side metallization 122 or the rear-side metallization segments 122a thereof, can include or be made of aluminum, e.g. by means of a printing process, e.g. made of an aluminum paste.

According to various embodiments, such a process of printing rear-side metallization segments 122a can be carried out on the rear-side of the so-called bifacial PERC cells. Alternatively or additionally, such a process of printing rear-side metallization segments 122a with bridges can be carried out for standard PERC cells.

If all LCO trenches 120 of a solar cell 100 are covered by the rear-side metallization 122, their alignment under the rear-side metallization 122 or rear-side metallization segments 122a thereof can be difficult. A poor alignment leads to an increased series resistance and to a reduced cell filling factor of the solar cell.

Therefore, for the rear-side metallization printing, e.g. for producing bifacial solar cells with rear-side metallization segments 122a or PERC cells with rear-side metallization 122a, it can be necessary to achieve an exact alignment of the LCO models 120 (LCO pattern, also referred to as LCO grating/grid) with reference to the printed rear-side metallization segments 122a (e.g. made of aluminum paste) (LCO can also be referred to as Laser Contact Opening).

Then, each of the local contact openings 120 can be completely covered (represented in dashed lines) by a rear-side metallization segment 122a. The further local contact openings 120a can respectively be partially covered by a rear-side metallization segment 122a and with the end section 120e thereof (compare FIG. 10) protruding beyond the rear-side metallization segment 122a.

For example, at least one of the local contact openings 120a, e.g. the first and/or the last further local contact opening 120a can extend beyond the ends of the rear-side metallization 122, as represented in FIG. 11, so that the end section 122e protrudes out of the rear-side metallization 122. In other words, the completely covered local contact openings 120 can be disposed between the partially exposed local contact openings 120a.

Thus, the end section 120e can be or remain visible during and after producing the solar cell 100. This enables to more easily check and correct the alignment of the rear-side metallization 122 and of the local contact openings 120 with respect to each other.

The rear-side metallization segments 122a can be aligned on the local contact openings 120 or are aligned for an optimized rear-side metallization segment LCO—layout. According to various embodiments, such an optimized alignment can be used for quadratic as well as for pseudo-quadratic cells.

According to various embodiments, the local contact opening 120a, which protrudes above the rear-side metallization 122, can be part of a continuous, or coherent opening, as represented in FIG. 11. In other words, the end sections 120e can be configured as linear trenches.

The coherent local contact opening 120a can evidently be easier to implement, e.g. without any need for significantly changing the process. However, the bead formations at the end sections 120e of the LCO 120 can be more difficult to suppress.

More the local contact openings 120a protrude beyond the edge of the rear-side metallization 122, more precisely the alignment of the rear-side metallization 122 and of the local contact openings 120, 120a with respect to each other can be carried out. However, with increasing number of the partially exposed local contact openings 120a (further LCO 120a), the number of beads increase, which form at the end of the LCO and are problematic for the stacking of the solar cells and for the classification/further processing.

If the Laser-Scanner-Speed in the last region (end section 120e) of the further contact openings 120 increases, the bead formation in this region can be minimized, or completely suppressed. In other words, by an adapted, e.g. increased Laser-Scanner-Speed (the speed, by which the Laser is guided) at the end sections 120e, the metal bead formation can be reduced or even avoided.

According to various embodiments, by such a layout, the elongation of the rear-side metallization segment screen (in case of screen printing) can be measured in comparison to the LCO—lines, e.g. after completion of the solar cell 100.

According to various embodiments, the alignment quality can be checked by such a layout and if necessary, can be corrected by electroluminescence imaging system (EL Images) or photoluminescence imaging system (PLRS Images), e.g. after completion of the solar cell 100.

According to various embodiments, the quality of the Laser process can be checked by such a layout, e.g. after the completion of the solar cell 100. For example, the misaligned field equalization (curvature of the Laser lines) can be recognized and corrected.

According to various embodiments, the use of separate dummy cells for the installation of the production facility and processes can be dispensed with.

According to various embodiments, the flat openings 126 can be or are formed, in which the plurality of rear-side metallization segments is or will be formed in the form of stripes (e.g. by means of a printing process). Therefore, the regions of the passivation layer 118 over which the flat openings 126 can be or shall be formed remain free from the rear-side metallization 122. The regions of the passivation layer 118 over which the flat openings 126 are or shall be formed can be disposed between the local contact openings 120.

In other words, the rear-side metallization 122 includes rear-side metallization segments in the form of stripes. For example, the rear-side metallization segments can be or are printed in the form of stripes, e.g. by means of a rear-side metallization segment screen (can also be referred to as template/stencil).

Alternatively to this, the flat openings 126 can be or are formed, in which a portion of the rear-side metallization 122 is or will be removed. Therefore, the portions of the rear-side metallization 122 over the regions of the passivation layer 118 over which the flat openings 126 can be or shall be formed, can be or are removed, e.g. by means of a Laser ablation process, an etching process or another process, which is suitable for localized elimination (or removal) of the rear-side metallization 122. In other words, the rear-side of the solar cell 100 can be or will be metallized on its entire surface (for forming the rear-side metallization 122) and thereafter can be or will be partially opened, e.g. flat (for forming the flat openings 126).

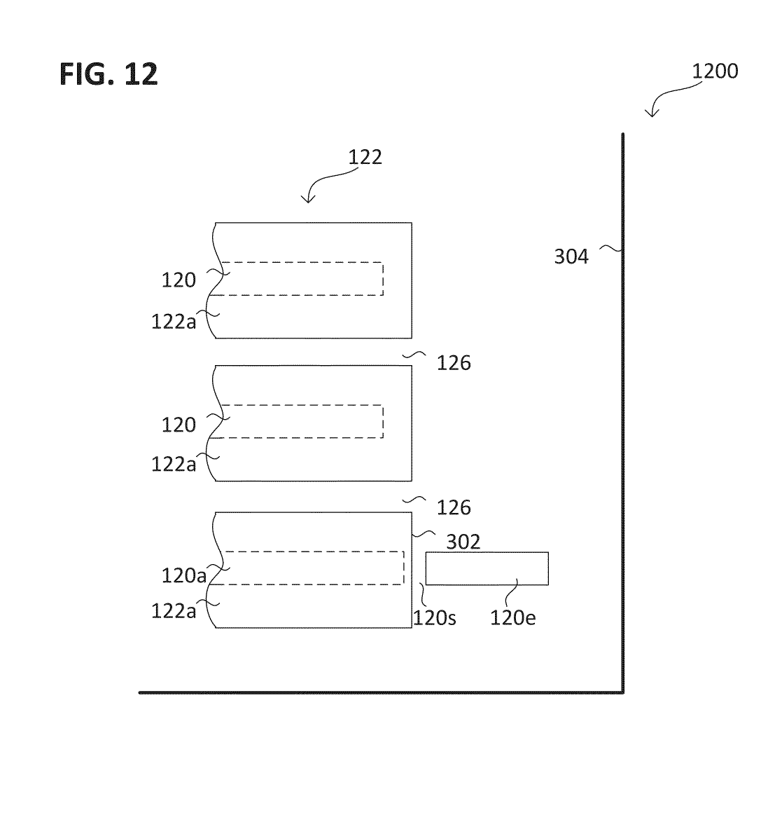

FIG. 12 shows a section of a rear-side view 1200 on a solar cell 100 according to various embodiments, similar to the view 1000.

According to various embodiments, the further LCO 120a, which protrudes beyond the rear-side metallization 122, can be part of an interrupted opening, i.e. an opening with several opening segments. In other words, the further LCO 120a includes at least one first opening segment, which is completely covered by the rear-side metallization 122, or one of the rear-side metallization segments 122a. Further, the other LCO 120a can include at least one second opening segment 120e (also referred to as end section), which is completely free. Both opening segments can be separated from each other by a bridge 120s and extend along a line.

The distance of the opening segments from each other, in other words, the width of the bridge 120s (transverse to the edge 302 of the rear-side metallization 122) can be in a range of approximately 10 μm to approximately 1 μm, e.g. at least 10 μm, preferably at least 50 μm, e.g. in a range of approximately 100 μm to approximately 500 μm.

The extension of the second opening segment 120e (along the direction of the width of the bridge 120s and transverse to the edge 302 of the rear-side metallization 122) can be in a range of approximately 10 μm to approximately 1 μm, e.g. at least 10 μm, preferably at least 50 μm, e.g. in a range of approximately 100 μm to approximately 500 μm. The extension of the second opening segment 120e can be less than the distance of the edge 302 of the rear-side metallization 122 to the edge 304 of the solar cell 100.

The bridge 120s can be formed, in which the Laser beam is interrupted, e.g. shielded or hidden for a short period during the formation of the LCO 120.

In other words, the end section 120e of the LCO 120a, which protrudes beyond the rear-side metallization 122, i.e. which is not covered by the rear-side metallization 122, can be separated by a bridge 120s (which is part of the passivation layer 118), in which the LCO 120a is interrupted. The bridge 120s can be partially covered by the rear-side metallization 122, i.e. that the edge 302 of the rear-side metallization 122, or of the respective rear-side metallization segment 122, beyond which the bridge 120s extends. In other words, the bridge 120s can be disposed on the edge of the rear-side metallization 122.

For the reason that the rear-side metallization 122 partially covers the bridge 120s, the distance thereof from the end section 120e of the further LCO 122a can be determined. In other words, the process of printing the rear-side metallization 122 can or will be aligned with the end section 120e of the further LCO 120a.

According to various embodiments, the bead formation can be further reduced by the bridge 120s on the edge of the rear-side metallization 122.

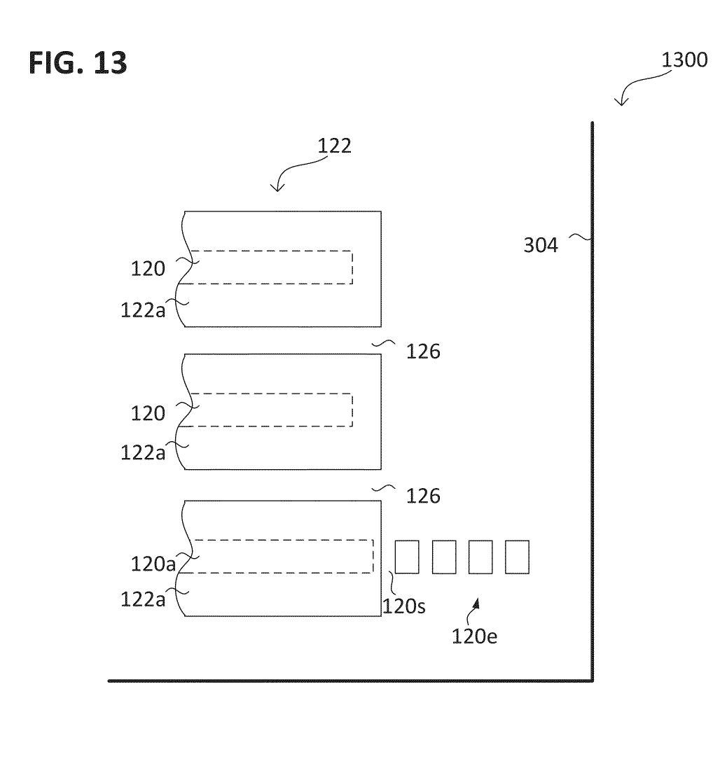

FIG. 13 shows a section of a rear-side view 1300 on a solar cell 100 according to various embodiments, similar to view 1000, wherein the end section 120e of the LCO 120a can include several segments.

These segments of the end section 120e can be formed, for example, by means of several single pulses of the Laser, e.g. in which the Laser beam is consecutively interrupted, e.g. shielded or hidden for several short periods during the formation of the LCO 120.

According to various embodiments, the formation of beads can be further reduced by forming the segments of the end section 120e.

What is claimed is:

1. A solar cell comprising:
a substrate with a front-side and a rear-side, wherein at least the front-side receives light,
a passivation layer on the rear-side of the substrate;
a plurality of local contact openings in the form of linear trenches, which pass through the passivation layer and partially expose the rear-side of the substrate; and
a first rear-side metallization on the passivation layer and in the local contact openings;
wherein the plurality of the local contact openings are disposed such that they are completely covered by the first rear-side metallization.

2. The solar cell of claim 1,
wherein the distance of the local contact openings to the edge of the first rear-side metallization is at least 10 μm, preferably at least 50 μm.

3. The solar cell of claim 1,
wherein the first rear-side metallization includes aluminum.

4. The solar cell of claim 1,
wherein the rear-side metallization comprises flat openings in the first rear-side metallization, which partially expose the passivation layer.

5. The solar cell of claim 4,
wherein a second, preferably well solderable metallization is disposed in the flat openings.

6. The solar cell of claim 5,
wherein the second metallization includes silver, nickel and/or zinc.

7. The solar cell of claim 4,
wherein the flat openings divide the first rear-side metallization into a plurality of rear-side metallization segments, which are respectively disposed at a distance from each other, wherein each contact opening of the plurality of local contact openings is completely covered by a rear-side metallization segment of the plurality of rear-side metallization segments.

8. The solar cell of claim 1, further comprising:
at least one more local contact opening in the form of a linear trench, which passes through the passivation layer and partially exposes the rear-side of the substrate, wherein the further local contact opening is formed such that this is partially covered by the first rear-side metallization.

9. The solar cell of claim 8,
wherein the further local contact opening is interrupted at one end section, which protrudes beyond the first rear-side metallization.

10. The solar cell of claim 1,
wherein silver is contained in the local contact openings for forming a respective local contact with the rear-side of the substrate.

11. The solar cell of claim 5,
wherein the second metallization is placed on the unopened passivation layer regions.

12. A method for manufacturing a solar cell, the method comprising:
forming a passivation layer on the rear-side of a substrate;
forming local contact openings through the passivation layer, so that the rear-side of the substrate is partially exposed; and
forming a first rear-side metallization on the passivation layer and in the local contact openings;
wherein the local contact openings are disposed such that they are completely covered by the rear-side metallization.

13. The method of claim 12,
wherein the local contact openings are formed by means of Laser beam.

14. The method of claim 13,
wherein the extension of the local contact openings is restricted by controlling the Laser beam.

15. The method of claim 13,
wherein the extension of the local contact openings is restricted by using at least one shadow-mask.

16. The method of claim 12,
wherein the local contact openings are etched.

17. The method of claim 12,
wherein the local contact openings are formed such that the distance from each single local contact opening of the local contact openings to the edge of the rear-side metallization is at least 10 μm, preferably at least 50 μm.

18. The method of claim 12,
wherein the first rear-side metallization includes flat openings, which partially expose the passivation layer;
wherein the flat openings divide the first rear-side metallization into a plurality of rear-side metallization segments, which are respectively disposed at a distance from each other, wherein each contact opening of the plurality of local contact openings is completely covered by a rear-side metallization segment of the plurality of rear-side metallization segments.

19. The method of claim 18,
wherein the flat openings are formed, in which the plurality of rear-side metallization segments is formed in the form of stripes; or wherein the flat openings are formed, in which a portion of the rear-side metallization is removed.

20. The method of claim 12, further comprising:
forming at least one more local contact opening in the form of a linear trench, which passes through the passivation layer and partially exposes the rear-side of the substrate, wherein the further contact opening is formed such that this is partially covered by the first rear-side metallization.

21. The method of claim 20,
wherein the further local contact opening is formed interrupted at one end section, which protrudes beyond the first rear-side metallization.
